(19) United States
(12) Patent Application Publication
(10) Pub. No.: US 2006/0071221 A1
(43) Pub. Date: Apr. 6, 2006

(54) Organic light emitting display and driving method thereof

(76) Inventors: Sung Chon Park, Suwon (KR); Choon Yul Oh, Gunpo (KR)

Correspondence Address: KNOBBE MARTENS OLSON & BEAR LLP, 2040 MAIN STREET, FOURTEENTH FLOOR, IRVINE, CA, 92614, US

(21) Appl. No.: 11/231,372

(22) Filed: Sep. 20, 2005

(30) Foreign Application Priority Data
Sep. 22, 2004 (KR) 10-2004-0075826

(51) Int. Cl. H01L 33/00

(52) U.S. Cl. 257/89

(57) ABSTRACT

An organic light emitting display and a driving method thereof, with an improved aperture ratio is disclosed. In one embodiment, the organic light emitting display comprises: a plurality of scan lines and a plurality of emission control lines, which are arranged in a horizontal direction; a plurality of data lines arranged in a vertical direction; and a pixel portion comprising a plurality of pixel circuits electrically connected to the scan line, the emission control line and the data line, wherein each pixel circuit is connected to two organic light emitting diodes placed on different two horizontal lines, and two emission control lines are connected to the organic light emitting diodes placed on two horizontal lines in a zigzag pattern. With this configuration, the present invention provides an organic light emitting display and a driving method thereof, in which organic light emitting diodes placed on two horizontal lines are controlled by one scan line, so that the number of scan lines can be decreased, thereby reducing manufacturing costs and enhancing the aperture ratio. Further, the organic light emitting diodes placed on two horizontal line are sequentially driven by one control circuit for one frame period, to further improve the aperture ratio.

### CROSS-REFERENCE TO RELATED APPLICATIONS

This application claims the benefit of Korean Patent Application No. 2004-75826, filed on Sep. 22, 2004, in the Korean Intellectual Property Office, the disclosure of which is incorporated herein by reference.

### BACKGROUND

1. Field of the Invention

The present invention relates to an organic light emitting display and a driving method thereof, and more particularly, to an organic light emitting display and a driving method thereof, in which an aperture ratio is improved.

2. Discussion of Related Technology

Recently, various light-weight flat panel displays have been developed which can be used advantageously as substitutes for a cathode ray tube (CRT) display since a CRT display is relatively heavy and bulky. Examples of flat panel displays include a liquid crystal display (LCD), a field emission display (FED), a plasma display panel (PDP), and an organic light emitting display (OLED), etc.

Among the flat panel displays, an organic light emitting display typically comprises a plurality of organic light emitting diodes, wherein each organic light emitting diode emits light by electron-hole recombination. Such an organic light emitting display has advantages in that response time is relatively fast and power consumption is relatively low. In this field of technology, an organic light emitting diode is also referred to an “OLED.” As used herein, OLED can refer to a diode or a display according to the context.

FIG. 1 is a plan view of a conventional organic light emitting display. FIG. 2 illustrates waveforms of signals for driving a conventional organic light emitting display.

Referring to FIG. 1, a conventional organic light emitting display comprises a pixel portion 30 comprising a plurality of pixels 40 formed adjacent to a region intersected by a plurality of scan lines S1 through Sn and a plurality of data lines D1 through Dm, a scan driver 20 to drive the scan lines S1 through Sn, and a data driver 20 to drive the data driver D1 through Dm.

The scan driver 20 generates a scan signal, and supplies the scan signals to the scan lines S1 through Sn in sequence (refer to FIG. 2). Further, the scan driver 20 generates an emission control signal EMI, and supplies the emission control signals to emission control lines E1 through En in sequence.

The data driver 10 supplies a data signal Ds to the data lines D1 through Dm every time when the scan signal is supplied as shown in FIG. 2. Here, in “DSx” of FIG. 2, ‘DS’ means the data signal, and ‘x’ means an x^{th} horizontal line. For example, “DS2” means the data signal transmitted to the second horizontal line.

The pixel portion 30 receives external first power VDD and external second power VSS. Here, the first power VDD and the second power VSS are supplied to the respective pixels 40. Each pixel 40 comprises a control circuit 42 and an organic light emitting diode 44. The control circuit 42 supplies current corresponding to the data signal DS to the organic light emitting diode 44, and the organic light emitting diode OLED emits light corresponding to the received current.

FIG. 3 is a circuit diagram of a conventional pixel structure. In FIG. 3, a pixel 40 placed on the first horizontal line is exemplarily illustrated.

Referring to FIG. 3, the conventional pixel 40 comprises the organic light emitting diode 44; and the control circuit 42 connected with the first data line D1, the first scan line S1, and the first emission control line E1, thereby controlling the organic light emitting diode 44 to emit light.

The organic light emitting diode 44 comprises an anode electrode connected to the control circuit 42, and a cathode electrode connected to a second power source VSS. Here, the organic light emitting diode 44 emits light corresponding to the current supplied from the control circuit 42.

The control circuit 42 comprises a first transistor M1, a second transistor M2, a third transistor M3, and a storage capacitor C. The first transistor M1 is turned on in response to a scan signal supplied to the first scan line S1. When the first transistor M1 is turned on, a data signal is supplied from the first data line D1 to the storage capacitor C. The storage capacitor C is charged with voltage corresponding to the data signal when the first transistor M1 is turned on.

The second transistor M2 supplies current corresponding to the voltage charged in the storage capacitor C to the third transistor M3. The third transistor M3 comprises a gate terminal connected to the first emission control line E1, a first terminal (source or drain terminal) connected to a second terminal of the second transistor M2. Further, the third transistor M3 comprises a second terminal connected to the organic light emitting diode OLED. Thus, the third transistor M3 controls the time that current flows from the second transistor M2 to the organic light emitting diode 44 in response to the emission control signal EMI supplied through the first emission control line E1.

In the conventional pixel 40, the storage capacitor C is charged with the voltage corresponding to the data signal in response to the scan signal, and the current corresponding to the voltage charged in the storage capacitor C is supplied to the organic light emitting diode 44, thereby emitting light. The emission time of the organic light emitting diode 44 is controlled by the emission control signal EMI.

The conventional organic light emitting display provides the control circuit 42 with each pixel 40. The control circuit 42 comprises at least two transistors and a capacitor, so that the control circuit 42 occupies a predetermined area of each pixel 40, thereby decreasing the aperture ratio of the pixel 40. Further, in the conventional organic light emitting display, every horizontal line comprises one scan line S and the emission control line E. As the scan line S is formed in every row of pixels, the aperture ratio is further decreased by the area that it occupies.

### SUMMARY OF CERTAIN INVENTIVE ASPECTS

Accordingly, it is an aspect of the present invention to provide an organic light emitting display and a driving method thereof, in which an aperture ratio is increased.

The foregoing and/or other aspects of the present invention are achieved by providing an organic light emitting display comprising a plurality of scan lines and a plurality of emission control lines, which are arranged in a horizontal direction; a plurality of data lines arranged in a vertical direction, and a pixel portion comprising a plurality of pixel circuits electrically connected to the scan line, the emission control line and the data line, wherein each pixel circuit is connected to two organic light emitting diodes placed on two separate (i.e., different) horizontal lines, and two emission control lines are “zigzag connected” to the organic light emitting diodes placed on two horizontal lines

According to an aspect of the invention, each scan line is provided in every two horizontal lines and connected to the pixel circuit.

According to an aspect of the invention, the emission control lines are provided in every horizontal line and connected to the pixel circuit.

According to an aspect of the invention, each pixel circuit comprises a driving unit connected to the scan line and the data line, a first sequence control unit connected between the driving unit and a first organic light emitting diode of two organic light emitting diodes, and a second sequence control unit connected between the driving unit and a second organic light emitting diode of the two organic light emitting diodes.

Other aspects of the present invention are achieved by providing an organic light emitting display including a scan driver to drive a plurality of scan lines and a plurality of emission control lines, a mapping unit to generate second data by rearranging external first data; a data driver to generate a data signal based on the second data and supply the data signal to a plurality of data lines, a pixel portion including a plurality of pixel circuits electrically connected to the scan lines, the emission control lines and the data lines, wherein the mapping unit generates the second data to zigzag supply the data signal to the organic light emitting diodes placed on different two horizontal lines.

According to an aspect of the invention, the pixel circuit is electrically connected to one scan line and two emission control lines. In a further aspect, one frame is divided into at least two fields. Also, the scan driver sequentially supplies scan signals to the scan lines in the respective fields.

Still another aspect of the invention is achieved by providing a method of driving an organic light emitting display, including controlling control circuits electrically connected to two organic light emitting diodes placed on separate horizontal lines so as to control the organic light emitting diodes placed on separate horizontal lines to emit light in a zigzag pattern for a first field period of a frame, and controlling the other organic light emitting diodes that do not emit light for the first period to emit light for a second field period of the frame.

According to an aspect of the invention, the organic light emitting diode that is disposed on an odd numbered vertical line among the organic light emitting diodes placed on a first horizontal line of the separate horizontal lines, and the organic light emitting diode that is disposed on an even numbered vertical line among the organic light emitting diodes placed on a second horizontal line of the separate horizontal lines, are controlled to emit light for the first field period.

According to an aspect of the invention, the organic light emitting diode that is disposed on the even numbered vertical line among the organic light emitting diodes placed on a first horizontal line of the separate horizontal lines, and the organic light emitting diode that is disposed on the odd numbered vertical line among the organic light emitting diodes placed on a second horizontal line of the separate horizontal lines, are controlled to emit light for the second field period.

### BRIEF DESCRIPTION OF THE DRAWINGS

These and/or other aspects and advantages of the invention will become apparent and more readily appreciated from the following description of the preferred embodiments, taken in conjunction with the accompanying drawings of which:

FIG. 1 is a schematic view illustrating a conventional organic light emitting display;

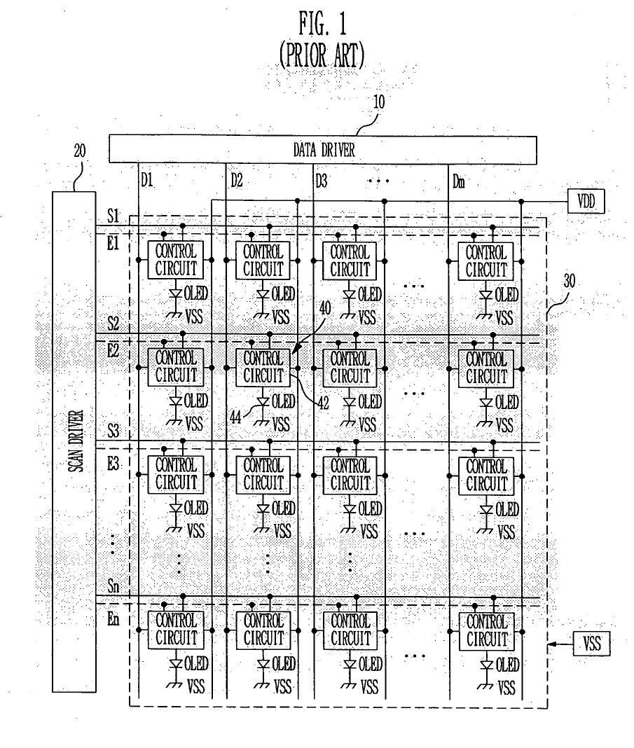

FIG. 2 illustrates waveforms of signals for driving the conventional organic light emitting display;

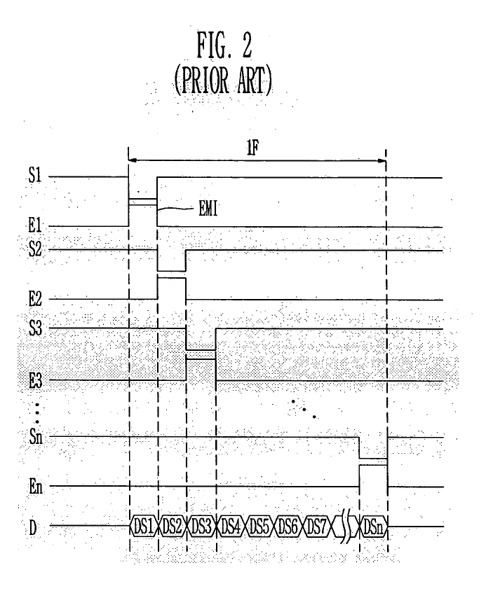

FIG. 3 is a circuit diagram illustrating a pixel shown in FIG. 1;

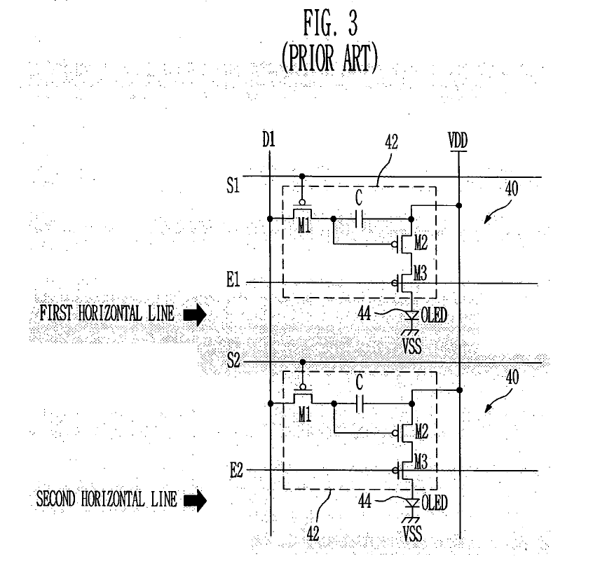

FIG. 4 is a schematic view illustrating an organic light emitting display according to an embodiment of the present invention;

FIG. 5 illustrates waveforms of signals for driving an organic light emitting display according to an embodiment of the present invention;

FIG. 6 illustrates waveforms of signals for driving an organic light emitting display according to an embodiment of the present invention;

FIG. 7 is a schematic view illustrating a pixel circuit shown in FIG. 4;

FIG. 8 is a schematic view illustrating a circuit diagram of a driving unit and a sequence control unit shown in FIG. 7;

FIG. 9 is a schematic view illustrating a circuit diagram of a driving unit and a sequence control unit shown in FIG. 7;

FIG. 10 is a block diagram illustrating the mapping unit shown in FIG. 4;

FIG. 11 is a table illustrating operations of the mapping unit shown in FIG. 10.

FIG. 12 is a table illustrating operations of the mapping unit shown in FIG. 10.

### DETAILED DESCRIPTION OF CERTAIN INVENTIVE ASPECTS

Hereinafter, embodiments according to the present invention will be described with reference to the accompanying drawings. Here, when one element is connected to another element, one element may be not only directly connected to another element but also indirectly connected to another element via another element. Further, some irrelevant or obvious elements may be omitted for clarity. Also, like reference numerals refer to like elements throughout.

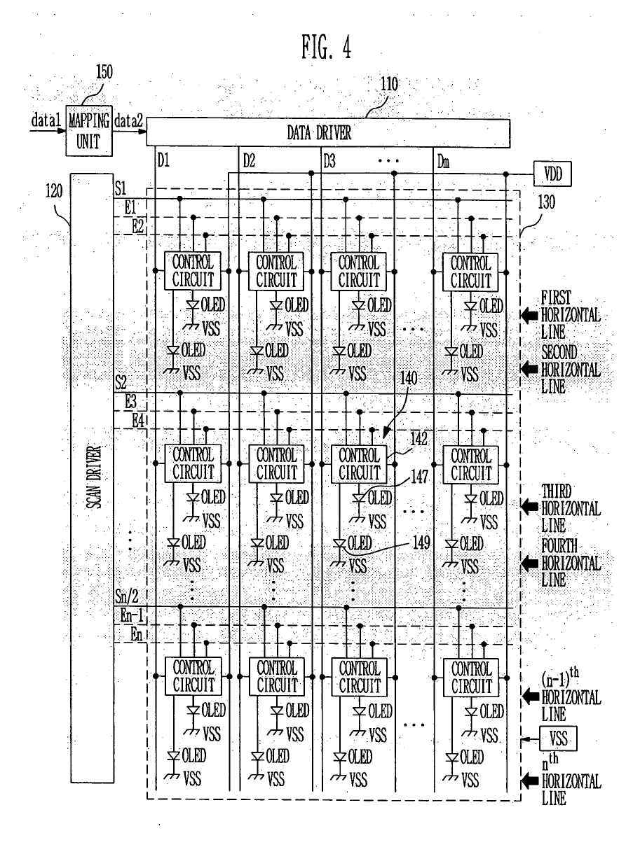

FIG. 4 is a schematic view illustrating an organic light emitting display according to an embodiment of the present invention. As illustrated in FIG. 4, an organic light emitting display according to an embodiment of the present invention comprises a pixel portion 130 comprising a pixel circuit 140 formed in an intersection region of scan lines S1 through Sn/2 and data lines D1 through Dm; a scan driver 120 to drive the scan lines S1 through Sn/2; a data driver 110 to drive the data lines D1 through Dm; and a mapping unit 150 to arrange external first data data1 and supply it to the data driver 110.

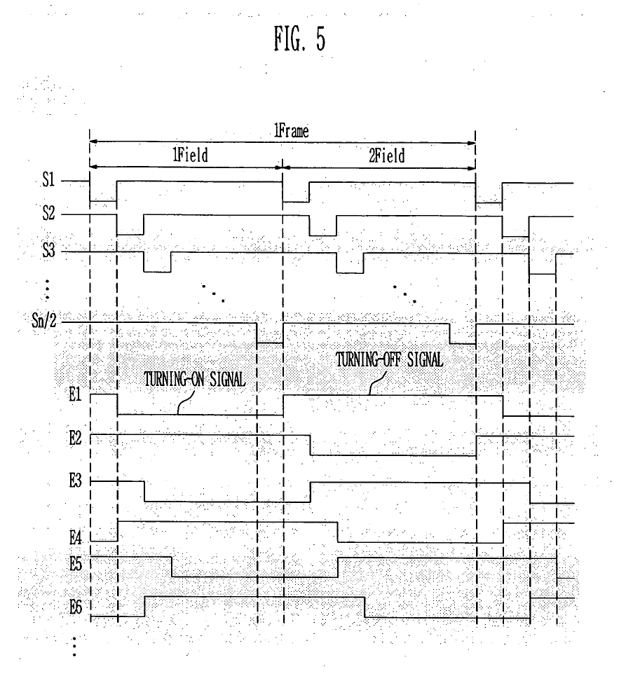

The scan driver 120 divides one frame of data into at least two fields, and supplies scan signals to the first scan line S1 through the (n/2)^{th} scan line Sn in each field, for example, field 1 and field 2 illustrated in FIG. 5. Further, the scan driver 120 supplies a turn-on signal (low signal) to odd numbered emission control lines E1, E3, . . . when the scan signals are sequentially supplied to the first scan line S1 through the (n/2)^{th} scan line Sn with regard to a first field. Here, the turn-on signal (low signal) supplied to the odd numbered emission control lines E1, E3, . . . is maintained for a period shorter than one field period, but a turn-off signal (high signal: emission control signal) is maintained for the other field period. Also, the scan driver 120 supplies a turn-on signal (low signal) to even numbered emission control lines E2, E4, . . . when the scan signals are sequentially supplied to the first scan line S1 through the (n/2)^{th} scan line Sn with regard to a second field. Here, the turn-on signal (low signal) supplied to the even numbered emission control lines E2, E4, . . . is maintained for a period shorter than one field period, but a turn-off signal (high signal emission control signal) is maintained for the other field period.

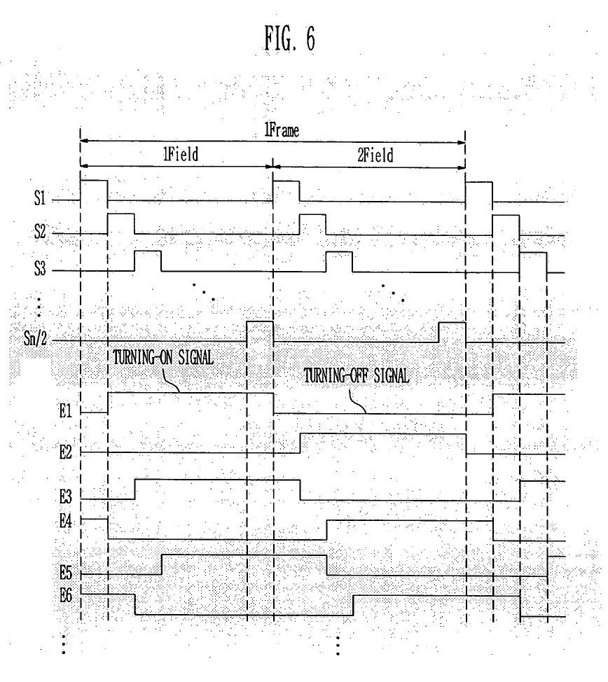

FIG. 5 illustrates waveforms of signals for driving the organic light emitting display according to an embodiment of the present invention. Waveforms shown in FIG. 5 are exemplary waveforms in an embodiment using p-type transistors in the pixel circuit 140. Alternatively, where n-type transistors are used in the pixel circuit 140, the waveforms are set as shown in FIG. 6. Here, the waveforms of FIG. 6 is in the inverse relation to those of FIG. 5, but they have the same supplying period e.g., the duration of field 1 and field 2 can be the same for either n or p-type transistors. Further, according to an embodiment of the present invention, the turn-on signals are sequentially supplied to the even numbered emission control lines E2, E4, . . . in the first field, and the turn-on signals are sequentially supplied to the odd numbered emission control lines E1, E3, . . . in the second field. The waveforms in FIGS. 5 and 6 are described in more detail further below.

Referring again to FIG. 4, the mapping unit 150 receives external data data 1 and rearranges data1 to generate second data data2. The mapping unit 150 supplies the second data data2 to the data driver 110. The mapping unit 150 will be described later in more detail.

The data driver 110 converts the second data data2 supplied from the mapping unit 150 into a data signal, and supplies the data signal to the pixel portion 130 via data lines D1 through Dm. The pixel portion 130 receives the data signal, and applies the data signals to the diodes in response to the scan signals.

The pixel portion 130 receives first power VDD and second power VSS from the outside. The first power VDD is supplied to the control circuit 142, and the second power VSS is supplied to a cathode electrode of the organic light emitting diode 147, 149 of the OLED. Further, each control circuit 142 is connected to two organic light emitting diodes 147, 149 of the organic light emitting display disposed on at least two horizontal lines (rows), thereby controlling the two organic light emitting diodes to emit light in sequence, for example. According to an embodiment of the present invention, the control circuit 142 controls the organic light emitting diodes of the OLED disposed on at least two horizontal lines. Other embodiments can include controlling more than the two horizontal lines of the OLED from the control circuit 142 which are illustrated.

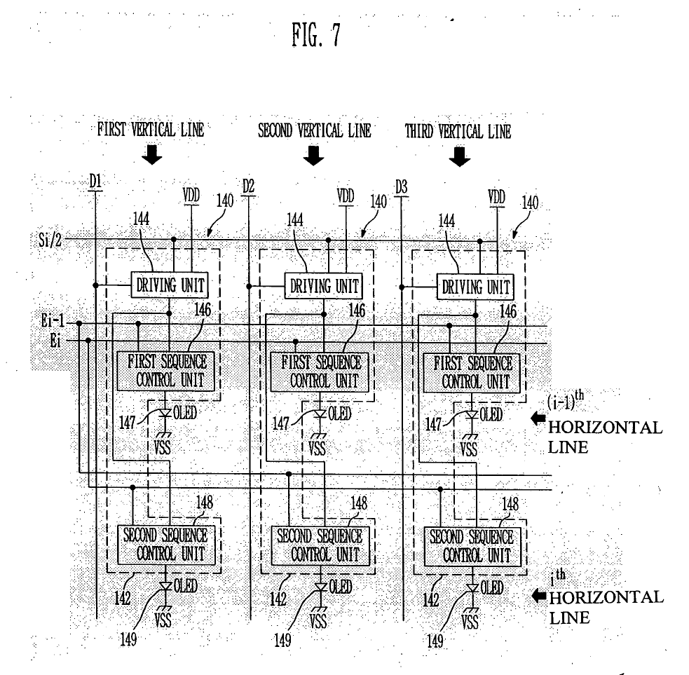

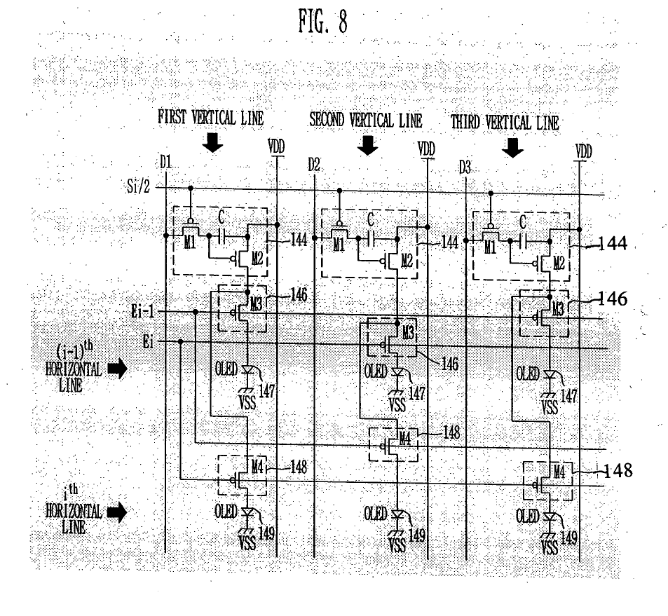

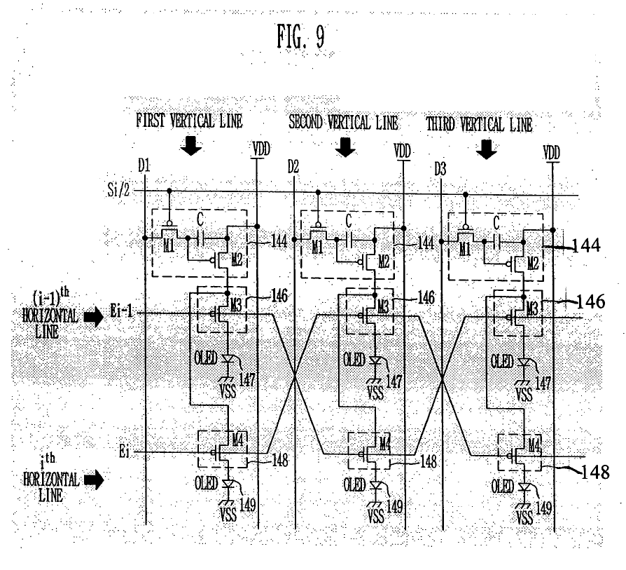

FIG. 7 is a schematic view of a pixel circuit illustrated in FIG. 4, and FIGS. 8 and 9 are circuit diagrams of a driving unit and a sequence control unit illustrated in FIG. 7. For the convenience of description, p-type transistors are illustrated in FIG. 8, but the invention is not limited to using p-type transistors. For example, in other embodiments the transistors may be n-type transistors.

Still referring to FIG. 7, according to an embodiment of the present invention each pixel circuit 140 in the OLED comprises at least two organic light emitting diodes disposed on different horizontal lines, and a control circuit 142 to control two organic light emitting diodes.

The control circuit 142 comprises a driving unit 144, a first sequence control unit 146, and a second sequence control unit 148. The driving unit 144 is connected to the scan line S and the data line D. Here, the driving unit 144 receives the data signal from the data line D when the scan signal is transmitted to the scan line S. Further, the driving unit 144 supplies current corresponding to the data signal to the first sequence control unit 146 and the second sequence control unit 148. For this, the driving unit 144 comprises the first transistor M1, the second transistor M2, and the storage capacitor C as shown in FIG. 8.

The first transistor M1 is turned on when the scan signal is supplied to the scan line S. When the first transistor M1 is turned on, the data signal is supplied from the data line D to the storage capacitor C. At this time, the storage capacitor C is charged with voltage corresponding to the data signal. The second transistor M2 supplies the current corresponding to the voltage charged in the storage capacitor C to the first sequence control unit 146 and the second sequence control unit 148.

The first sequence control unit 146 is connected to the organic light emitting diode 147 disposed on the (i−1)^{th} horizontal line (odd numbered horizontal line, where i is a natural number). Here, the first sequence control unit 146 supplies the current from the driving unit 144 to the organic light emitting diode 147 in response to the turn-on signal supplied from the emission control line E connected thereto. For this, the first sequence control unit 146 comprises a third transistor M3 connected between the organic light emitting diode 147 and the driving unit 144.

The second sequence control unit 148 is connected to the organic light emitting diode 149 disposed on the i^{th} horizontal line (even numbered horizontal line). Here, the second sequence control unit 148 supplies the current from the driving unit 144 to the organic light emitting diode 149 in response to the turn-on signal supplied from the emission control line E connected to the second sequence control unit 148. For this, the second sequence control unit 148 comprises a fourth transistor M4 connected between the organic light emitting diode 149 and the driving unit 144.

According to an embodiment of the present invention, each emission control line E is “zigzag connected” to the organic light emitting diodes. In this embodiment, the emission control lines are connected to the organic light emitting diodes through the sequence control unit. An example of being zigzag connected is a configuration where two emission control lines are connected to organic light emitting diodes that are arranged in multiple vertical columns and two adjacent horizontal lines in the pixel portion 30 of the organic light emitting display. In this example, the first control emission line is connected to a first, third, fifth, etc. organic light emitting diode on the first horizontal line and the second, fourth, sixth, etc. organic light emitting diode on the second horizontal line, and the second emission line is connected to a second, fourth, sixth, etc. organic light emitting diode on the first horizontal line and the first, third, fifth, etc organic light emitting diode on the second horizontal line. Thus, in this example, an emission line is not connected to two adjacent organic light emitting diodes in a vertical column or horizontal line direction, and the connections of an emission line with organic light emitting diodes in the two horizontal lines appears to zigzag between the two horizontal line. Accordingly, light emitted by the zigzag connected organic light emitting diodes in this example is in a zigzag pattern. Other embodiments of a zigzag connection are also possible.

Still referring to the embodiment shown in FIG. 7, the emission lines are zigzag connected to the (i−1)^{th} emission control line Ei−1 is connected to the first sequence control unit 146 that is disposed on the odd numbered vertical line among the first sequence control units 146 placed on the (i−1)^{th} horizontal line. Further, the (i−1)^{th} emission control line Ei−1 is connected to the second sequence control unit 148 that is disposed on the even numbered vertical line among the second sequence control units 148 placed on the i^{th} horizontal line. That is, the (i−1)^{th} emission control line Ei−1 is alternately zigzag connected to the first sequence control unit 146 placed on the (i−1)^{th} horizontal line and the second sequence control unit 148 placed on the i^{th} horizontal line. Then, when the turn-on signal is supplied to the (i−1)^{th} emission control line Ei−1, the organic light emitting diode emits light as a zigzag shape, which is advantageous for preventing the undesirable stripes-pattern typically associated with a horizontal line unit.

FIG. 9 illustrates the zigzag connection between the i^{th} emission control line Ei and the (i+1)^{th} emission control line Ei−1. Alternatively, according to an embodiment of the present invention, the (i+1)^{th} emission control line Ei−1 can be connected to both the first sequence control unit 146 disposed on the even numbered vertical line among the first sequence control units 146 placed on the (i−1)^{th} horizontal line and the second sequence control unit 148 disposed on the odd numbered vertical line among the second sequence control units 148 placed on the i^{th} horizontal line.

The i^{th} emission control line is connected to the first sequence control unit 146 that is disposed on the even numbered vertical line among the first sequence control units 146 placed on the (i−1)^{th} horizontal line. Further, the i^{th} emission control line Ei is connected to the second sequence control unit 148 that is disposed on the odd numbered vertical line among the second sequence control units 148 placed on the i^{th} horizontal line. That is, the i^{th} emission control line Ei is alternately zigzag connected to the first sequence control unit 146 placed on the (i−1)^{th} horizontal line and the second sequence control unit 148 placed on the i^{th} horizontal line. Then, when the turn-on signal is supplied to the i^{th} emission control line Ei, the organic light emitting diode OLED emits light as a zigzag shape, thereby preventing stripes-pattern noise from arising.

Alternatively, according to an embodiment of the present invention, the i^{th} emission control line Ei can be connected to both the first sequence control unit 146 disposed on the odd numbered vertical line among the first sequence control units 146 placed on the (i−1)^{th} horizontal line and the second sequence control unit 148 disposed on the even numbered vertical line among the second sequence control units 148 placed on the i^{th} horizontal line.

Referring again to FIG. 5, and in accordance with FIGS. 4 and 8, the scan signals are sequentially transmitted to the first scan line S1 through the (n/2)^{th} scan line Sn/2 during the first field Field 1 of a frame of data1Frame. When the scan signal is transmitted to the (i−1)^{th} scan line Si−1, the first transistor M1 provided in the driving unit 144 is turned on. At this time, the data driver 110 supplies a data signal to the odd numbered data lines D1, D3 . . . wherein the data signal is transmitted to the organic light emitting diodes placed on the (i−1)^{th} horizontal line and the i^{th} horizontal line of the OLED. Furthermore, the data driver 110 supplies a data signal to the even numbered data lines D2, D4, . . . , wherein the data signal is transmitted to the organic light emitting diodes placed on the i^{th} horizontal line (or the (i−1)^{th} horizontal line) of the OLED.

Then, the data signal is transmitted from the data lines D to the storage capacitor C. Therefore, the storage capacitor C is charged with voltage corresponding to the data signal. After the storage capacitor C is charged with the voltage corresponding to the data signal, the second transistor M2 supplies current corresponding to the data signal to the third transistor M3 and the fourth transistor M4. At this time, the turn-on signal is transmitted to the (i−1)^{th} emission control line Ei−1. Then, the third transistor M3 or the fourth transistor M4 connected zigzag with the (i−1)^{th} emission control line Ei−1 are turned on, thereby controlling the organic light emitting diode OLED to emit light.

According to one embodiment, the scan signals are sequentially transmitted to the first scan line S1 through the (n/2)^{th} scan line Sn/2 in the second field. Here, when the scan signal is transmitted to the (i−1)^{th} scan line Si−1, the first transistor M1 provided in the driving unit 144 is turned on. At this time, the data driver 110 supplies the data signal to the data lines D1, D3, . . . , wherein the data signal is transmitted to the organic light emitting diode OLED placed on the i^{th} horizontal line (or the (i−1)^{th} horizontal line). Also, the data driver 110 supplies the data signal to the even numbered data lines D2, D4, . . . , wherein the data signal is transmitted to the organic light emitting diode OLED placed on the (i−1)^{th} horizontal line (or the i^{th} horizontal line).

Then, the data signal is transmitted from the data lines D to the storage capacitor C. Therefore, the storage capacitor C is charged with voltage corresponding to the data signal. After the storage capacitor C is charged with the voltage corresponding to the data signal, the second transistor M2 supplies current corresponding to the data signal to the third transistor M3 and the fourth transistor M4. At this time, the turn-on signal is transmitted to the i^{th} emission control line Ei. Then, the fourth transistor M4 or the third transistor M3 connected zigzag with the (i−1)^{th} emission control line Ei−1 are turned on, thereby controlling the organic light emitting diode OLED to emit light.

Thus, according to an embodiment of the present invention, one frame of data is divided into two fields, and the organic light emitting diodes placed on two horizontal lines of the OLED are controlled in a zigzag configuration to emit light for the respective field periods, thereby displaying an image. For displaying a frame of data, the organic light emitting diodes placed on two horizontal lines of the OLED are driven in a zigzag manner for different periods, respectively. The human eye recognizes the organic light emitting diodes of the OLED located on two horizontal lines as being operated at the same time, thereby normally displaying an image.

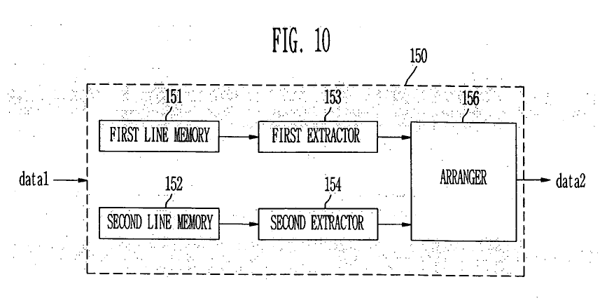

FIG. 10 is a block diagram of an embodiment of the mapping unit 150 shown in FIG. 4.

According to an embodiment of the present invention the mapping unit 150 comprises a first line memory 151, coupled to a first extractor 153, which is coupled to an arranger 156. The mapping unit 150 also includes a second line memory 152, is coupled to a second extractor 154, and the arranger 156.

Each of the first line memory 151 and the second line memory 152 temporarily stores the external first data data1 for two adjacent horizontal lines. For example, the first line memory 151 stores the first data data1 to be supplied to the (i−1)^{th} horizontal line, and the second line memory 152 stores the first data data1 to be supplied to the i^{th} horizontal line.

Referring also now to FIG. 10, the first extractor 153 extracts the data to be supplied from the first line memory 151 to the odd numbered vertical line (or the even numbered vertical line). The second extractor 154 extracts the data to be supplied from the second line memory 152 to the even numbered vertical line (or the odd numbered vertical line). Thus, the second extractor 154 extracts the data to be supplied to the even numbered vertical line when the first extractor 153 extracts the data to be supplied to the odd numbered vertical line. On the other hand, the second extractor 154 extracts the data to be supplied to the odd numbered vertical line when the first extractor 153 extracts the data to be supplied to the even numbered vertical line.

The arranger 156 generates the second data data2 on the basis of the data extracted by the first and second extractors 153 and 154, and supplies the second data data2 to the data driver 110.

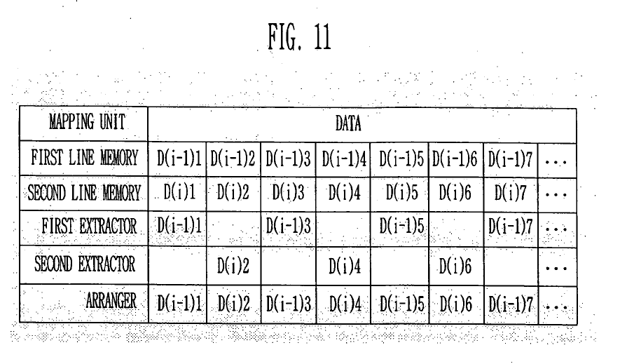

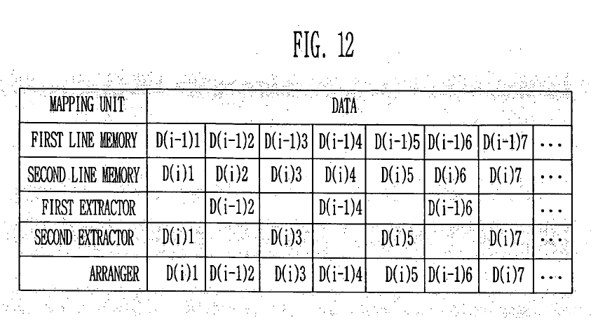

Hereinbelow, operations of the mapping unit 150 will be described with reference to FIGS. 11 and 12. For a predetermined period of the first field period, as shown in FIG. 11, the first line memory 151 stores the data to be supplied to the (i−1)^{th} horizontal line, and the second line memory 152 stores the data to be supplied to the i^{th} horizontal line. At this time, the first extractor 153 extracts the data to be supplied from the first line memory 151 to the odd numbered vertical lines (i.e., odd numbered data lines). In other words, the first extractor 153 extracts the data corresponding to D(i−1)1, D(i−1)3, D(i−1)3, . . . In “D(x)y”, ‘D’ means the data, ‘(x)’ means the horizontal line, and ‘y’ means the vertical line. For example, D(i−1)1 means the data to be supplied to the first vertical line of the (i−1)^{th} horizontal line. Further, the second extractor 154 extracts the data to be supplied from the second line memory 152 to the even numbered vertical lines (e.g., even numbered data lines). In other words, the second extractor 154 extracts the data corresponding to D(i)2, D(i)4, D(i)6, . . .

After the first extractor 153 and the second extractor 154 extract the data, the arranger 156 arranges the data extracted by the first extractor 153 and the second extractor 154, thereby generating the second data data2. Here, the arranger 156 alternately arranges the data extracted by the first extractor 153 and the data extracted by the second extractor 154, thereby generating the second data data2. Then, the second data data2 generated by the arranger 156 is transmitted to the data driver 110. Then, the data driver 110 generates the data signal based on the second data data2, and supplies the data signal to the data lines D. Substantially, the mapping unit 150 supplies the second data data2 to the data driver 110 while repeating the foregoing operations for the first field period, thereby supplying the data signal to the organic light emitting diodes OLED emitting light as a zigzag shape.

For a predetermined period of the second field period, as shown in FIG. 12, the first line memory 151 stores the data to be supplied to the (i−1)^{th} horizontal line, and the second line memory 152 stores the data to be supplied to the i^{th} horizontal line. At this time, the first extractor 153 extracts the data to be supplied from the first line memory 151 to the even numbered vertical lines. In other words, the first extractor 153 extracts the data corresponding to D(i−1)2, D(i−1)4, D(i−1)6, . . . Further, the second extractor 154 extracts the data to be supplied from the second line memory 152 to the odd numbered vertical lines. In other words, the second extractor 154 extracts the data corresponding to D(i)1, D(i)3, D(i)5, . . .

After the first extractor 153 and the second extractor 154 extract the data, the arranger 156 arranges the data extracted by the first extractor 153 and the second extractor 154, thereby generating the second data data2. Here, the arranger 156 alternately arranges the data extracted by the first extractor 153 and the data extracted by the second extractor 154, thereby generating the second data data2. Then, the second data data2 generated by the arranger 156 is transmitted to the data driver 110. Then, the data driver 110 generates the data signal based on the second data data2, and supplies the data signal to the data lines D. Substantially, the mapping unit 150 supplies the second data data2 to the data driver 110 while repeating the foregoing operations for the second field period, thereby supplying the data signal to the organic light emitting diodes OLED emitting light as a zigzag shape.

Alternatively, according to an embodiment of the present invention, the data may be mapped as shown in FIG. 12 for the first field period, and mapped as shown in FIG. 11 for the second field period.

As described above, the present invention provides an organic light emitting display and a driving method thereof, in which organic light emitting diodes placed on two horizontal lines are controlled by one scan line, so that the number of scan lines can be decreased, thereby reducing production cost and enhancing the aperture ratio. Further, the organic light emitting diodes placed on two horizontal lines are sequentially driven by one control circuit for one frame period, so that the aperture ratio is further improved.

Although various embodiments of the present invention have been shown and described, it will be appreciated by skilled technologists that changes be made in these embodiments without departing from the principles and spirit of the invention, the scope of which is defined in the claims and their equivalents.

What is claimed is:

1. An organic light emitting display comprising:
a plurality of scan lines arranged in a horizontal direction;
a plurality of emission control lines arranged in the horizontal direction;
a plurality of data lines arranged in a vertical direction; and
a pixel portion comprising a plurality of pixel circuits electrically connected to the scan line, the emission control line and the data line,
wherein each pixel circuit is connected to two organic light emitting diodes placed on different two horizontal lines, and two emission control lines are zigzag connected to the organic light emitting diodes placed on two horizontal lines.

2. The organic light emitting display according to claim 1, wherein each scan line is provided in every two horizontal lines and connected to the pixel circuit.

3. The organic light emitting display according to claim 2, wherein the emission control lines are provided in every horizontal line and connected to the pixel circuit.

4. The organic light emitting display according to claim 1, wherein each pixel circuit comprises:
a driving unit connected to the scan line and the data line;
a first sequence control unit connected between the driving unit and a first organic light emitting diode between two organic light emitting diodes; and
a second sequence control unit connected between the driving unit and a second organic light emitting diode between two organic light emitting diodes.

5. The organic light emitting display according to claim 4, wherein the (i−1)^{th} emission control line is connected to the first sequence control unit that is disposed on a odd numbered vertical line among the first sequence control units placed on the (i−1)^{th} horizontal line, and is connected to the second sequence control unit that is disposed on an even numbered vertical line among the second sequence control units placed on the i^{th} horizontal line, where i is a natural number.

6. The organic light emitting display according to claim 5, wherein the i^{th} emission control line is connected to the first sequence control unit that is disposed on the even numbered vertical line among the first sequence control units placed on the (i−1)^{th} horizontal line, and is connected to the second sequence control unit that is disposed on the odd numbered vertical line among the second sequence control units placed on the i^{th} horizontal line.

7. The organic light emitting display according to claim 4, wherein the (i−1)^{th} emission control line is connected to the first sequence control unit that is disposed on an even numbered vertical line among the first sequence control units placed on the (i−1)^{th} horizontal line, and is connected to the second sequence control unit that is disposed on the odd numbered vertical line among the second sequence control units placed on the i^{th} horizontal line, where i is a natural number.

8. The organic light emitting display according to claim 7, wherein the i^{th} emission control line is connected to the first sequence control unit that is disposed on the odd numbered vertical line among the first sequence control units placed on the (i−1)^{th} horizontal line, and is connected to the second sequence control unit that is disposed on the even numbered vertical line among the second sequence control units placed on the i^{th} horizontal line.

9. The organic light emitting display according to claim 4, wherein the driving unit comprises:
a first transistor connected to the scan line and the data line;
a storage capacitor to be charged with voltage corresponding to a data signal transmitted though the data line;
a second transistor to supply current corresponding to the voltage charged in the storage capacitor.

10. The organic light emitting display according to claim 9, wherein the first sequence control unit comprises a third transistor connected between the second transistor and the first organic light emitting diode.

11. The organic light emitting display according to claim 9, wherein the second sequence control unit comprises a fourth transistor connected between the second transistor and the second organic light emitting diode.

12. An organic light emitting display comprising:
a scan driver to drive a plurality of scan line and a plurality of emission control lines;
a mapping unit to generate second data by rearranging external first data;
a data driver to generate a data signal based on the second data and supply the data signal to a plurality of data lines;
a pixel portion comprising a plurality of pixel circuits electrically connected to the scan lines, the emission control lines and the data lines,
wherein the mapping unit generates the second data to zigzag supply the data signal to the organic light emitting diodes placed on different two horizontal lines.

13. The organic light emitting display according to claim 12, wherein the pixel circuit is electrically connected to one scan line and two emission control lines.

14. The organic light emitting display according to claim 13, wherein one frame is divided at least two fields.

15. The organic light emitting display according to claim 14, wherein the scan driver sequentially supplies scan signals to the scan lines in the respective fields.

16. The organic light emitting display according to claim 15, wherein the scan driver sequentially supplies turning-on signals to an odd numbered emission control line among the emission control lines while sequentially supplying the scan signals to the scan lines in a first field period between two fields, and sequentially supplies the turning-on signals to an even numbered emission control line among the emission control lines while sequentially supplying the scan signals to the scan lines in a second field period.

17. The organic light emitting display according to claim 15, wherein the scan driver sequentially supplies turning-on signals to an even numbered emission control line among the emission control lines while sequentially supplying the scan signals to the scan lines in a first field period between two fields, and sequentially supplies the turning-on signals to an odd numbered emission control line among the emission control lines while sequentially supplying the scan signals to the scan lines in a second field period.

18. The organic light emitting display according to claim 16, wherein the supplying period of the turning-on signal is shorter than each field period.

19. The organic light emitting display according to claim 14, wherein the mapping unit comprises:
first and second line memories to store first data corresponding to one horizontal line, respectively;
a first extractor to extract some data from the first data stored in the first line memory;
a second extractor to extract some data from the second data stored in the second line memory; and
an arranger to generate the second data by rearranging the data extracted by the first and second extractors.

20. The organic light emitting display according to claim 19, wherein the first extractor extracts the first data to be supplied to an odd numbered data line from the first data stored in the first line memory in the first field period between two fields, and the second extractor extracts the first data to be supplied to an even numbered data line from the first data stored in the second line memory in the first field period between two fields.

21. The organic light emitting display according to claim 20, wherein the first extractor extracts the first data to be supplied to the even numbered data line from the first data stored in the second line memory in the first field period between two fields, and the second extractor extracts the first data to be supplied to the odd numbered data line from the first data stored in the second line memory in the second field period between two fields.

22. The organic light emitting display according to claim 19, wherein the first extractor extracts the first data to be supplied to an even numbered data line from the first data stored in the first line memory in the first field period between two fields, and the second extractor extracts the first data to be supplied to an odd numbered data line from the first data stored in the second line memory in the first field period between two fields.

23. The organic light emitting display according to claim 22, wherein the first extractor extracts the first data to be supplied to the odd numbered data line from the first data stored in the second line memory in the first field period between two fields, and the second extractor extracts the first data to be supplied to the even numbered data line from the first data stored in the second line memory in the second field period between two fields.

24. The organic light emitting display according to claim 19, wherein the arranger alternately arranges the first data extracted by the first and second extractors to generate the second data.

25. The organic light emitting display according to claim 14, wherein each pixel circuit comprises:
a driving unit connected to the scan line and the data line;
a first sequence control unit connected between the driving unit and a first organic light emitting diode between two organic light emitting diodes; and
a second sequence control unit connected between the driving unit and a second organic light emitting diode between two organic light emitting diodes.

26. The organic light emitting display according to claim 25, wherein the (i−1)^{th} emission control line is connected to the first sequence control unit that is disposed on a odd numbered vertical line among the first sequence control units placed on the (i−1)^{th} horizontal line, and is connected to the second sequence control unit that is disposed on an even numbered vertical line among the second sequence control units placed on the i^{th} horizontal line, where i is a natural number.

27. The organic light emitting display according to claim 26, wherein the i^{th} emission control line is connected to the first sequence control unit that is disposed on the even numbered vertical line among the first sequence control units placed on the (i-1)^{th} horizontal line, and is connected to the second sequence control unit that is disposed on the odd numbered vertical line among the second sequence control units placed on the i^{th} horizontal line.

28. The organic light emitting display according to claim 25, wherein the (i−1)^{th} emission control line is connected to the first sequence control unit that is disposed on an even numbered vertical line among the first sequence control units placed on the (i−1)^{th} horizontal line, and is connected to the second sequence control unit that is disposed on the odd numbered vertical line among the second sequence control units placed on the i^{th} horizontal line, where i is a natural number.

29. The organic light emitting display according to claim 28, wherein the i^{th} emission control line is connected to the first sequence control unit that is disposed on the odd numbered vertical line among the first sequence control units placed on the (i−1)^{th} horizontal line, and is connected to the second sequence control unit that is disposed on the even numbered vertical line among the second sequence control units placed on the i^{th} horizontal line.

30. The organic light emitting display according to claim 25, wherein the driving unit comprises:
a first transistor connected to the scan line and the data line;
a storage capacitor to be charged with voltage corresponding to a data signal transmitted though the data line;
a second transistor to supply current corresponding to the voltage charged in the storage capacitor.

31. The organic light emitting display according to claim 30, wherein the first sequence control unit comprises a third transistor connected between the second transistor and the first organic light emitting diode.

32. The organic light emitting display according to claim 30, wherein the second sequence control unit comprises a fourth transistor connected between the second transistor and the second organic light emitting diode.

33. A method of driving an organic light emitting display, comprising:
controlling control circuits electrically connected two organic light emitting diodes placed different horizontal lines to control the organic light emitting diodes placed difference horizontal lines to zigzag emit light for a first field period of a frame; and
controlling the other organic light emitting diodes that does not emit light for the first period to emit light for a second field period of the frame.

34. The method according to claim 33, wherein the organic light emitting diode that is disposed on an odd numbered vertical line among the organic light emitting diodes placed on a first horizontal line of the different horizontal lines, and the organic light emitting diode that is disposed on an even numbered vertical line among the organic light emitting diodes placed on a second horizontal line of the different horizontal lines, are controlled to emit light for the first field period.

35. The method according to claim 34, wherein the organic light emitting diode that is disposed on the even numbered vertical line among the organic light emitting diodes placed on a first horizontal line of the different horizontal lines, and the organic light emitting diode that is disposed on the odd numbered vertical line among the organic light emitting diodes placed on a second horizontal line of the different horizontal lines, are controlled to emit light for the second field period.

36. The method according to claim 33, wherein the organic light emitting diode that is disposed on an even numbered vertical line among the organic light emitting diodes placed on a first horizontal line of the different horizontal lines, and the organic light emitting diode that is disposed on an odd numbered vertical line among the organic light emitting diodes placed on a second horizontal line of the different horizontal lines, are controlled to emit light for the first field period.

37. The method according to claim 36, wherein the organic light emitting diode that is disposed on the odd numbered vertical line among the organic light emitting diodes placed on a first horizontal line of the different horizontal lines, and the organic light emitting diode that is disposed on the even numbered vertical line among the organic light emitting diodes placed on a second horizontal line of the different horizontal lines, are controlled to emit light for the second field period.

38. An organic light emitting display comprising:
a plurality of scan lines arranged in a horizontal direction;
a plurality of emission control lines arranged in the horizontal direction;
a plurality of data lines arranged in a vertical direction; and
a scan driver to drive the plurality of scan lines and the plurality of emission control lines;
a mapping unit to generate second data by rearranging external first data;
a data driver to generate a data signal based on the second data and supply the data signal to the plurality of data lines;
a pixel portion comprising a plurality of pixel circuits electrically connected to the scan lines, the emission control lines and the data lines, wherein each of said pixel circuits comprise two organic light emitting diodes disposed on different horizontal lines of the organic light emitting display,
wherein the second data mapping unit generates the second data used to supply the drive signal to the pixel circuits, and
wherein the scan driver supplies a drive signal based on the second data to drive light emitting diodes to emit light in a zigzag pattern.

39. The organic light emitting display according to claim 38, wherein each pixel circuit is electrically connected to one scan line and two emission control lines.

40. The organic light emitting display according to claim 38, wherein the second data is divided into a plurality of frames, and wherein each frame is divided into at least two fields.

41. The organic light emitting display according to claim 40, wherein the organic light emitting diodes are configured to correspond to two fields.

42. The organic light emitting display according to claim 38, wherein the scan driver sequentially supplies scan signals to the scan lines in the respective two fields.

43. The organic light emitting display according to claim 38, wherein the scan driver sequentially supplies turn-on signals to an odd numbered emission control line among the emission control lines while sequentially supplying the scan signals to the scan lines in a first field display period, and sequentially supplies the turn-on signals to an even numbered emission control line among the emission control lines while sequentially supplying the scan signals to the scan lines in a second field display period.

44. The organic light emitting display according to claim 43, wherein the scan driver sequentially supplies turn-on signals to an even numbered emission control line among the emission control lines while sequentially supplying the scan signals to the scan lines in a first field display period, and sequentially supplies the turn-on signals to an odd numbered emission control line among the emission control lines while sequentially supplying the scan signals to the scan lines in a second field display period.

45. The organic light emitting display according to claim 43, wherein the supplying period of the turn-on signal is shorter than each field period.

46. The organic light emitting display according to claim 40, wherein the mapping unit comprises:
first and second line memories to store first data corresponding to one horizontal line, respectively;
a first extractor to extract selected data from the first data stored in the first line memory;
a second extractor to extract selected data from the second data stored in the second line memory; and
an arranger to generate the second data by rearranging the data extracted by the first and second extractors.

47. The organic light emitting display according to claim 46, wherein the first extractor extracts the first data to be supplied to an odd numbered data line from the first data stored in the first line memory in the first field period between two fields, and the second extractor extracts the first data to be supplied to an even numbered data line from the first data stored in the second line memory in the first field period between two fields.

48. The organic light emitting display according to claim 47, wherein the first extractor extracts the first data to be supplied to the even numbered data line from the first data stored in the second line memory in the first field period between two fields, and the second extractor extracts the first data to be supplied to the odd numbered data line from the first data stored in the second line memory in the second field period between two fields.

49. The organic light emitting display according to claim 46, wherein the first extractor extracts the first data to be supplied to an even numbered data line from the first data stored in the first line memory in the first field period between two fields, and the second extractor extracts the first data to be supplied to an odd numbered data line from the first data stored in the second line memory in the first field period between two fields.

50. The organic light emitting display according to claim 49, wherein the first extractor extracts the first data to be supplied to the odd numbered data line from the first data stored in the second line memory in the first field period between two fields, and the second extractor extracts the first data to be supplied to the even numbered data line from the first data stored in the second line memory in the second field period between two fields.

51. The organic light emitting display according to claim 46, wherein the arranger alternately arranges the first data extracted by the first and second extractors to generate the second data.

52. The organic light emitting display according to claim 40, wherein each pixel circuit comprises:
a driving unit connected to a scan line and a data line;
a first sequence control unit connected between the driving unit and a first one of the organic light emitting diodes; and
a second sequence control unit connected between the driving unit and a second one of the organic light emitting diodes.

53. The organic light emitting display according to claim 52, wherein the (i−1)^{th} emission control line is connected to the first sequence control unit that is disposed on a odd numbered vertical line among the first sequence control units placed on the (i−1) horizontal line, and is connected to the second sequence control unit that is disposed on an even numbered vertical line among the second sequence control units placed on the i^{th} horizontal line, where i is a natural number.

54. The organic light emitting display according to claim 53, wherein the i^{th} emission control line is connected to the first sequence control unit that is disposed on the even numbered vertical line among the first sequence control units placed on the (i−1)^{th} horizontal line, and is connected to the second sequence control unit that is disposed on the odd numbered vertical line among the second sequence control units placed on the i^{th} horizontal line.

55. The organic light emitting display according to claim 52, wherein the (i−1)^{th} emission control line is connected to the first sequence control unit that is disposed on an even numbered vertical line among the first sequence control units placed on the (i−1)^{th} horizontal line, and is connected to the second sequence control unit that is disposed on the odd numbered vertical line among the second sequence control units placed on the i^{th} horizontal line, where i is a natural number.

56. The organic light emitting display according to claim 55, wherein the i^{th} emission control line is connected to the first sequence control unit that is disposed on the odd numbered vertical line among the first sequence control units placed on the (i−1)^{th} horizontal line, and is connected to the second sequence control unit that is disposed on the even numbered vertical line among the second sequence control units placed on the i^{th} horizontal line.

57. The organic light emitting display according to claim 52, wherein the driving unit comprises:
a first transistor connected to the scan line and the data line;
a storage capacitor to be charged with voltage corresponding to a data signal transmitted though the data line; and
a second transistor to supply current corresponding to the voltage charged in the storage capacitor.

58. The organic light emitting display according to claim 57, wherein the first sequence control unit comprises a third transistor connected between the second transistor and the first organic light emitting diode.

59. The organic light emitting display according to claim 57, wherein the second sequence control unit comprises a fourth transistor connected between the second transistor and the second organic light emitting diode.

60. A method of driving an organic light emitting display, comprising:
controlling a plurality of control circuits, each continual circuit being electrically connected to two organic light emitting diodes placed on different horizontal lines, to emit light for a first field period of a frame in a first zigzag pattern; and
controlling the organic light emitting diodes that do not emit light for the first period to emit light for a second field period of the frame in a second zigzag pattern.

61. The method according to claim 60, wherein the organic light emitting diode that is disposed on an odd numbered vertical line among the organic light emitting diodes is placed on a first horizontal line of the different horizontal lines, and the organic light emitting diode that is disposed on an even numbered vertical line among the organic light emitting diodes is placed on a second horizontal line of the different horizontal lines, are controlled to emit light for the first field period.

62. The method according to claim 61, wherein the organic light emitting diode that is disposed on the even numbered vertical line among the organic light emitting diodes is placed on a first horizontal line of the different horizontal lines, and the organic light emitting diode that is disposed on the odd numbered vertical line among the organic light emitting diodes is placed on a second horizontal line of the different horizontal lines, are controlled to emit light for the second field period.

63. The method according to claim 62, wherein the organic light emitting diode that is disposed on an even numbered vertical line among the organic light emitting diodes is placed on a first horizontal line of the different horizontal lines, and the organic light emitting diode that is disposed on an odd numbered vertical line among the organic light emitting diodes is placed on a second horizontal line of the different horizontal lines, are controlled to emit light for the first field period.

64. The method according to claim 63, wherein the organic light emitting diode that is disposed on the odd numbered vertical line among the organic light emitting diodes is placed on a first horizontal line of the different horizontal lines, and the organic light emitting diode that is disposed on the even numbered vertical line among the organic light emitting diodes is placed on a second horizontal line of the different horizontal lines, are controlled to emit light for the second field period.
